(19) United States
(12) Patent Application Publication
(10) Pub. No.: US 2004/0135198 A1
(43) Pub. Date: Jul. 15, 2004

(54) Semiconductor device and method of fabricating the same, nonvolatile semiconductor memory and method of fabricating the same, and electronic apparatus including nonvolatile semiconductor memory

(75) Inventor: Yuuichiro Murahama, Mie (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 10/623,520

(22) Filed: Jul. 22, 2003

(30) Foreign Application Priority Data
Jul. 23, 2002 (JP) 2002-213839

(51) Int. Cl. H01L 29/76

(52) U.S. Cl. 257/330

(57) ABSTRACT

A semiconductor device according to an aspect of the present invention having a first gate insulating film formed in a first active region of a semiconductor substrate and having a first film thickness, and a second gate insulating film formed in a second active region of the semiconductor substrate and having a second film thickness smaller than the first film thickness, wherein a semiconductor substrate surface in the first active region is lower than that in the second active region is provided.

### CROSS REFERENCE TO RELATED APPLICATION

This application is based upon and claims benefit of priority under 35 USC 119 from the Japanese Patent Applications No. 2002-213839, filed on Jul. 23, 2002 and No. 2003-196056, filed on Jul. 11, 2003, the entire contents of which are incorporated herein by reference.

### BACKGROUND OF THE INVENTION

The present invention relates to a semiconductor device and a method of fabricating the same, a nonvolatile semiconductor memory and a method of fabricating the same, and an electronic apparatus including the nonvolatile semiconductor memory.

When oxide films having different film thicknesses are to be formed in a conventional semiconductor device, an oxide film having a first film thickness is formed on a semiconductor substrate by thermal oxidation and left in one active region by using photolithography and etching. Then, an oxide film having a second film thickness different from the first film thickness is formed in another active region by using thermal oxidation as in the above process. In this manner, oxide films different in film thickness are formed on the same semiconductor substrate.

Since, however, these oxide films have different film thicknesses, desired patterning is difficult to perform when a gate electrode material is deposited after the oxide films are formed or the deposited gate electrode material is patterned by, e.g., photolithography and reactive ion etching (to be referred to as RIE hereinafter), or when a buried insulating film is subjected to chemical mechanical polishing (to be referred to as CMP hereinafter) after an element isolation region is formed. In some cases, the influence of a pattern defect or the like in the active region poses a problem such as an initial defect of the oxide film or a short device life.

Also, an element isolation method using a trench forms a trench in a silicon substrate and forms an element isolation region by burying an insulating film in the trench by chemical vapor deposition (to be referred to as CVD hereinafter) or the like. Alternatively, trench element isolation is performed after a gate insulating film is formed on a semiconductor substrate.

A method of forming oxide films having different film thicknesses and performing element isolation by using a trench will be explained below with reference to the accompanying drawings.

As shown in FIG. 1, a silicon oxide film 302 is formed on a semiconductor substrate 301 by thermal oxidation.

As shown in FIG. 2, a photoresist film 304 is formed by photolithography and so patterned as to remove a region not covered with the photoresist film 304 by wet etching or RIE using hydrogen fluoride or ammonium fluoride.

In the region not covered with the photoresist film 304, a silicon oxide film 303 different in film thickness from the silicon oxide film 302 is formed by similar thermal oxidation. In this way, as shown in FIG. 3, the silicon oxide films 302 and 303 different in film thickness are formed on the same semiconductor substrate 301.

As shown in FIG. 4, a polysilicon film 305 as a gate electrode material of a first layer and a silicon nitride film 306 serving as a stopper in CMP are formed in this order.

As shown in FIG. 5, a photoresist film 307 covering an active region is formed by photolithography. Patterning is performed by using this photoresist film 307 such that the silicon oxide film 302, polysilicon film 305, and silicon nitride film 306 in the active region are left behind, and the films in an element isolation region are removed. In addition, a trench is formed by performing RIE on a surface portion of the semiconductor substrate 301 in the element isolation region. As a consequence, a step 350 is formed on the bottom surface of a trench 320 in the semiconductor substrate 301, so a region in which a thin gate insulting film is to be formed is lower than a region in which a thick gate insulating film is to be formed as shown in FIG. 5. After that, as shown in FIG. 6, the photoresist film 307 is removed.

As shown in FIG. 7, the trench 320 is filled by depositing a silicon oxide film 311 by CVD or the like.

Since projections and recesses are present in the active region and element isolation region on the surface of the silicon oxide film 311, the surface is planarized by using CMP. The surface height of the silicon nitride film 306 on the thick silicon oxide film 302 differs from that of the silicon nitride film 306 on the thin silicon oxide film 303. However, the silicon oxide film 311 on the silicon nitride film 306 must be completely removed. Therefore, CMP must be performed to a height indicated by an alternate long and short dashed line L shown in FIG. 7, thereby polishing the surface of the silicon nitride film 306 as shown in FIG. 8. Since a large amount of the surface of a silicon nitride film 306a on the thick silicon oxide film 302 is polished, a film thickness X1 of the silicon nitride film 306a is smaller than a film thickness X2 of a silicon nitride film 306b on the thin silicon oxide film 303.

In gate electrode processing to be performed later, the processing margin deteriorates if the step beside the element isolation region is large. To reduce this step in advance, therefore, ammonium fluoride or the like is used to etch the silicon oxide film 311 in the element isolation region as shown in FIG. 9, thereby decreasing the height of the silicon oxide film 311.

As shown in FIG. 10, the silicon nitride films 306a and 306b on the polysilicon film 305 are removed by RIE, chemical dry etching, or wet etching using, e.g., phosphoric acid.

Then, a process of removing a natural oxide film present on the surface of the polysilicon film 305 is performed. After that, a polysilicon film is deposited, and a gate electrode 307 is obtained as shown in FIG. 11 through photolithography and RIE.

In the step of processing the silicon oxide film 311 shown in FIG. 9, the silicon nitride film 306a on the thick silicon oxide film 302 is thinner than the silicon nitride film 306b on the thin silicon oxide film 303 as described above. So, an etching solution such as ammonium fluoride advances from the interface to etch a portion close to the silicon oxide film 302. Since the silicon oxide film 302 functions as a gate insulating film, a problem such as an initial defect of the gate insulating film or a short life arises. In addition, if a defect is caused in the gate insulating film, the gate electrode 305 made of a polysilicon film formed later may contact the silicon substrate 301 in the active region, thereby causing a potential junction defect.

### SUMMARY OF THE INVENTION

According to one aspect of the present invention, a semiconductor device comprising a first gate insulating film formed in a first active region of a semiconductor substrate and having a first film thickness, and a second gate insulating film formed in a second active region of said semiconductor substrate and having a second film thickness smaller than the first film thickness, wherein a semiconductor substrate surface in the first active region is lower than that in the second active region is provided.

According to another aspect of the present invention, a semiconductor device comprising a first gate insulating film formed in a first active region of a semiconductor substrate and having a first film thickness; a second gate insulating film formed in a second active region of said semiconductor substrate and having a second film thickness smaller than the first film thickness; and a trench element isolation insulating region formed between the first and second active regions, wherein a first height which is a surface height of said semiconductor substrate in the first active region on a bottom surface of the trench element isolation region is lower than a second height which is a surface height of said semiconductor substrate in the second active region on the bottom surface of the trench element isolation region is provided.

According to one aspect of the present invention, a method of fabricating a semiconductor device comprising a first gate insulating film formed in a first active region of a semiconductor substrate and having a first film thickness, and a second gate insulating film formed in a second active region of the semiconductor substrate and having a second film thickness smaller than the first film thickness, comprising, processing a surface portion of the semiconductor substrate such that a semiconductor substrate surface in the first active region is lower than that in the second active region is provided.

According to one aspect of the present invention, a semiconductor device fabrication method comprising, forming a mask which exposes a surface of a first active region and covers a second active region of a semiconductor substrate; forming a first oxide film on the surface of the first active region by oxidation by using the mask; removing the mask and first oxide film to make a semiconductor substrate surface in the first active region lower than that in the second active region; forming a second oxide film on the surfaces of the first and second active regions; leaving a portion of the second oxide film behind in the first active region and removing a portion of the second oxide film from the second active region; and forming a third oxide film thinner than the second oxide film on a surface of the second oxide film in the first active region of the semiconductor substrate, and forming a fourth oxide film having a film thickness substantially equal to that of the third oxide film on the surface of the second active region, wherein a first gate insulating film including the second and third oxide films is formed in the first active region, a second gate insulating film including the fourth oxide film in the second active region, and a surface height of the first gate insulating film is substantially equal to that of the second gate insulating film is provided.

According to one aspect of the present invention, a nonvolatile semiconductor memory comprising a memory cell array and peripheral circuit, wherein a transistor included in said peripheral circuit has a first gate insulating film formed in a first active region of a semiconductor substrate and having a first film thickness, a transistor included in said memory cell array has a second gate insulating film formed in a second active region of said semiconductor substrate and having a second film thickness smaller than the first film thickness, and a semiconductor substrate surface in the first active region is lower than that in the second active region is provided.

According to another aspect of the present invention, a nonvolatile semiconductor memory comprising a memory cell array and peripheral circuit, wherein a transistor included in said peripheral circuit has a first gate insulating film formed in a first active region of a semiconductor substrate and having a first film thickness, a transistor included in said memory cell array has a second gate insulating film formed in a second active region of said semiconductor substrate and having a second film thickness smaller than the first film thickness, and on a bottom surface of a trench element isolation insulating region formed between the first and second active regions, a first height of a surface of said semiconductor substrate in the first active region is lower than a second height of the surface of said semiconductor substrate in the second active region is provided.

According to one aspect of the present invention, a method of fabricating a nonvolatile semiconductor memory comprising a memory cell array and peripheral circuit, wherein a transistor included in the peripheral circuit has a first gate insulating film having a first film thickness in a first active region of a semiconductor substrate, and, a transistor included in the memory cell array has a second gate insulating film having a second film thickness smaller than the first film thickness in a second active region of the semiconductor substrate, and the method comprises, processing a surface portion of the semiconductor substrate such that a surface of the semiconductor substrate in the first active region is lower than that of the semiconductor substrate in the second active region is provided.

According to one aspect of the present invention, an electronic apparatus comprising, a card interface, a card slot connected to said card interface, and an electronic card capable of being electrically connected to said card slot, wherein said electronic card comprises the above nonvolatile semiconductor memory is provided.

According to one aspect of the present invention, the above apparatus is one of a digital still camera, video camera, television, audio apparatus, game apparatus, electronic musical instrument, cellular phone, personal computer, personal digital assistant, voice recorder and PC card.

### BRIEF DESCRIPTION OF THE DRAWINGS

FIGS. 1 to 11 are longitudinal sectional views showing the sectional structure of a conventional semiconductor device and a method of fabricating the same;

FIGS. 12 to 25 are longitudinal sectional views showing the sectional structure of a semiconductor device according to the first embodiment of the present invention and a method of fabricating the same;

FIG. 26 is a longitudinal sectional view showing the sectional structure of the semiconductor device according to the first embodiment;

FIG. 27 is a longitudinal sectional view showing the sectional structure of a conventional semiconductor device;

FIGS. 28 to 41 are longitudinal sectional views showing the sectional structure of a semiconductor device according to the second embodiment of the present invention and a method of fabricating the same;

FIG. 42 is a plan view showing the layout of a nonvolatile semiconductor memory according to the third embodiment of the present invention;

FIG. 43 is a plan view comparing a memory array cell region with a peripheral circuit region in the nonvolatile semiconductor memory according to the third embodiment;

FIG. 44 is a longitudinal sectional view showing a longitudinal section taken along a line A-A in FIG. 43;

FIG. 45 is a block diagram showing an electronic card according to the fourth embodiment of the present invention, which uses the nonvolatile semiconductor memory according to the third embodiment, and the arrangement of an electronic apparatus according to the fifth embodiment of the present invention, which can use the electronic card;

FIG. 46 is a block diagram showing the arrangement of the electronic apparatus; and

FIGS. 47 to 56 are views for explaining practical examples of the electronic apparatus.

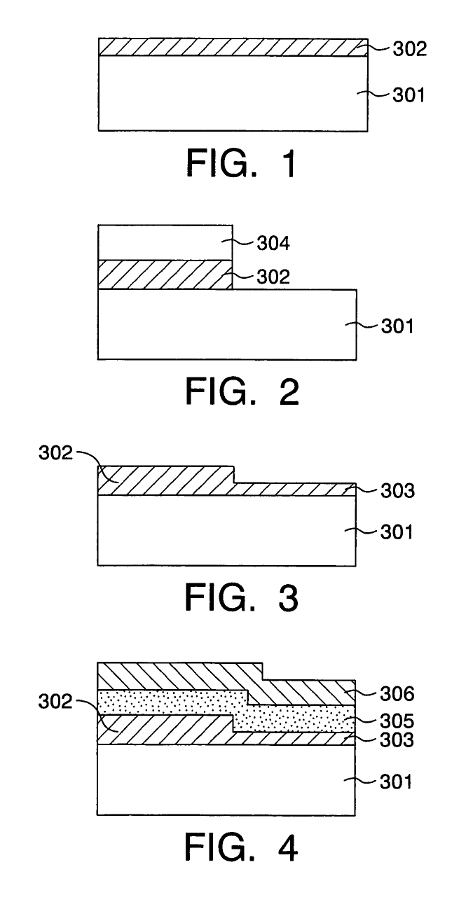

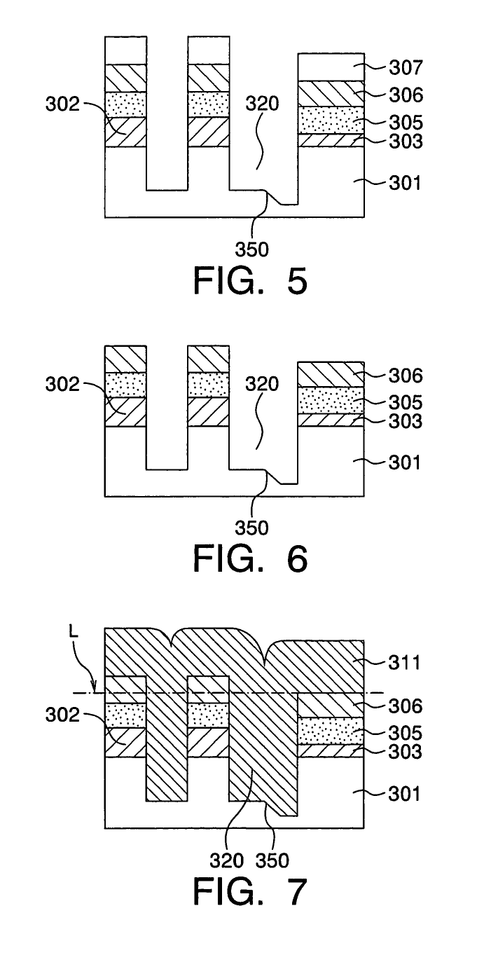

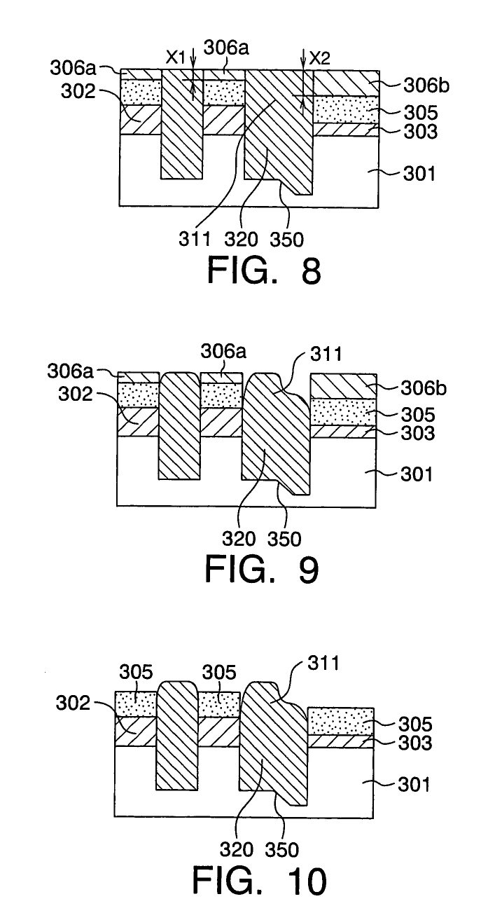

### DESCRIPTION OF THE PREFERRED EMBODIMENTS

Embodiments of the present invention will be described below with reference to the accompanying drawings.

### (1) First Embodiment

FIGS. 12 to 25 illustrate the arrangement of a semiconductor device according to the first embodiment of the present invention, and a method of fabricating the same.

As shown in FIG. 12, a silicon oxide film 102 about 1,000 Å thick is formed on a semiconductor substrate 101, and a silicon nitride film 103 about 1,000 Å thick is formed on the surface of the silicon oxide film 102. The silicon nitride film 103 is formed to protect a region except for a region where a thick gate insulating film is to be formed.

As shown in FIG. 13, a resist film 104 is formed on the silicon nitride film 103 by photolithography except for the region where a thick gate insulating film is to be formed.

As shown in FIG. 14, the resist film 104 is used as a mask to pattern the silicon nitride film 103 by RIE. In addition, wet etching is performed to pattern the silicon oxide film 102 below the silicon nitride film 103, thereby opening the region where a thick silicon oxide film is to be formed and exposing the surface of the semiconductor substrate 101.

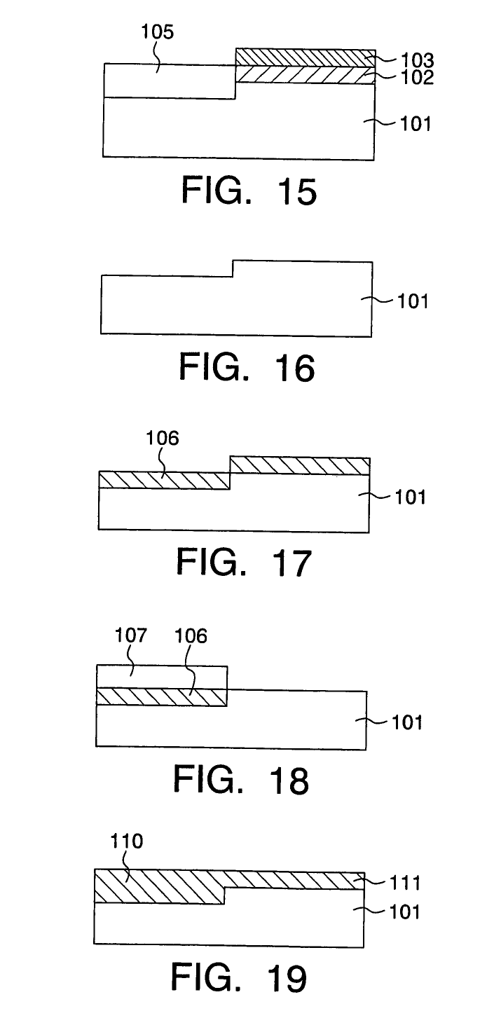

As shown in FIG. 15, a silicon oxide film 105 about 640 Å thick is formed by oxidation in a region not covered with the silicon nitride film 103. In this oxidation step, LOCOS or the like can also be used. Consequently, a step (in this embodiment, about 320 Å thick) is formed on the substrate level between the surface of the semiconductor substrate 101 in the region where the silicon oxide film 105 is formed, and the surface of the semiconductor substrate 101 in the region protected by the silicon nitride film 103.

This step on the substrate level is formed so that when gate insulating films having different film thicknesses are formed in subsequent steps, the heights of the surfaces of these gate insulating films are the same. Accordingly, the silicon oxide film 105 must be so formed as to have a film thickness by which the surface of the semiconductor substrate 101 is lowered by the difference (about 320 Å) between the film thicknesses of the gate insulating films.

As shown in FIG. 16, the silicon nitride film 103 is removed by wet etching using phosphoric acid or the like, and the silicon oxide films 105 and 102 are removed by wet etching using hydrogen fluoride, ammonium fluoride, or the like.

As shown in FIG. 17, to form a thick gate insulating film, a silicon oxide film 106 having a desired film thickness (in this embodiment, about 320 Å) is formed by thermal oxidation. As a consequence, the silicon oxide film 106 is formed in both the region where a thick gate insulating film is to be formed and a region where a thin gate insulating film is to be formed.

As shown in FIG. 18, a resist film 107 which protects the region where a thick gate insulating film is to be formed is formed by photolithography. Wet etching is performed by using the resist film 107 as a mask to remove the silicon oxide film 106 from the region where a thin gate insulating film is to be formed.

As shown in FIG. 19, a silicon oxide film is formed on the entire surface by thermal oxidation. That is, silicon oxide films having substantially the same film thickness (in this embodiment, about 80 Å) are formed on the silicon oxide film 106 in the region where a thick gate insulating film is to be formed, and on the semiconductor substrate 101 in the region where a thin gate insulating film is to be formed. As a consequence, a gate insulating film 110 about 400 Å thick is formed in the region where a thick gate insulating film is to be formed, and a gate insulating film 111 about 80 Å thick is formed in the region where a thin gate insulating film is to be formed.

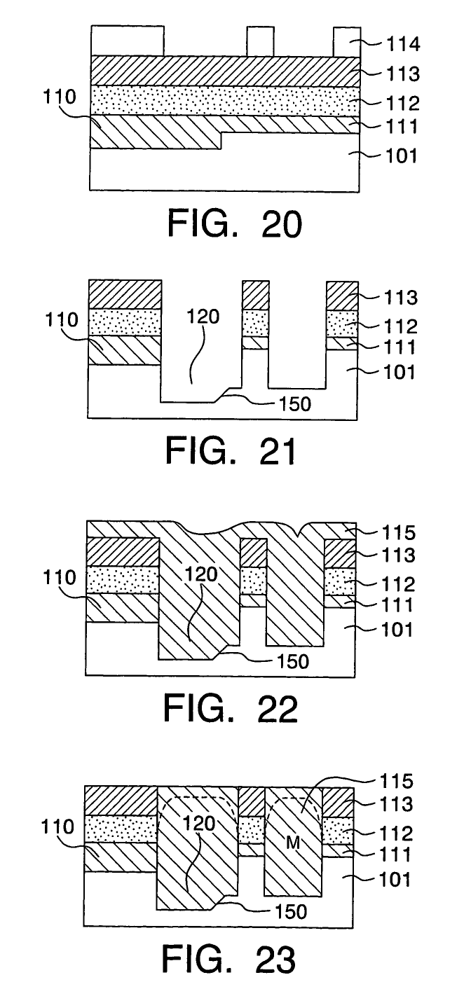

As shown in FIG. 20, on the gate insulating films 110 and 111, a polysilicon film 112 about 100 Å thick as a gate electrode material and a silicon nitride film 113 about 1,000 Å thick serving as a polishing stopper in CMP are formed in this order. In addition, a resist film 114 for protecting an active region is formed by photolithography except for an element isolation region.

As shown in FIG. 21, the resist film 114 is used to pattern the polysilicon film 112 and silicon nitride film 113, and a trench 120 is formed in the semiconductor substrate 101 in the element isolation region by RIE.

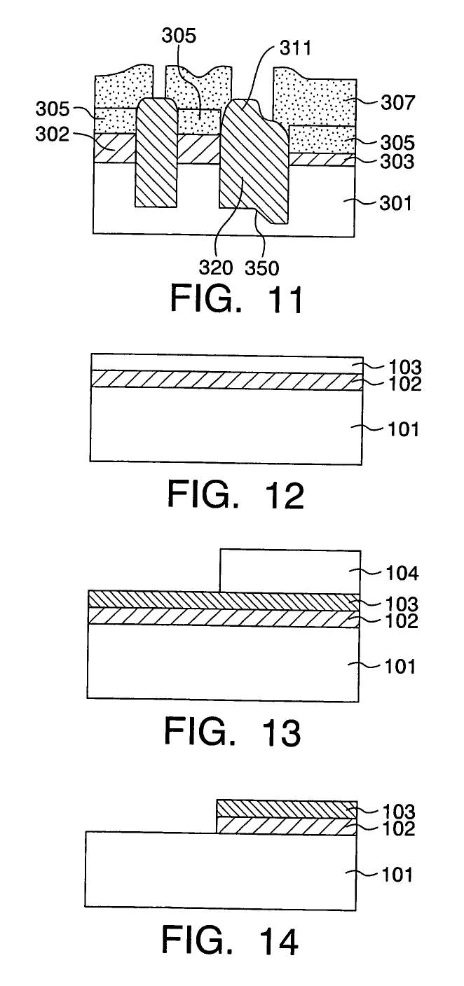

In this state, a step 150 is formed on the bottom surface of the trench 120 in the semiconductor substrate 101. The direction of the step 150 differs from that of the step 350 in the conventional device explained with reference to FIG. 11; the step 150 rises from the region where the thick gate insulating film 110 is formed toward the region where the thin gate insulating film 111 is formed.

As shown in FIG. 22, a silicon oxide film 115 is deposited to fill the trench 120 by CVD.

As shown in FIG. 23, the silicon nitride film 113 is used as a stopper to perform CMP, thereby planarizing the silicon oxide film 115.

In gate electrode processing to be performed later, the processing margin deteriorates if the height of the step beside the element isolation region is large. To reduce this sep in advance, therefore, wet etching is performed for the silicon oxide film 115 in the element isolation region by using ammonium fluoride or the like, thereby decreasing the height as indicated by a dotted line M.

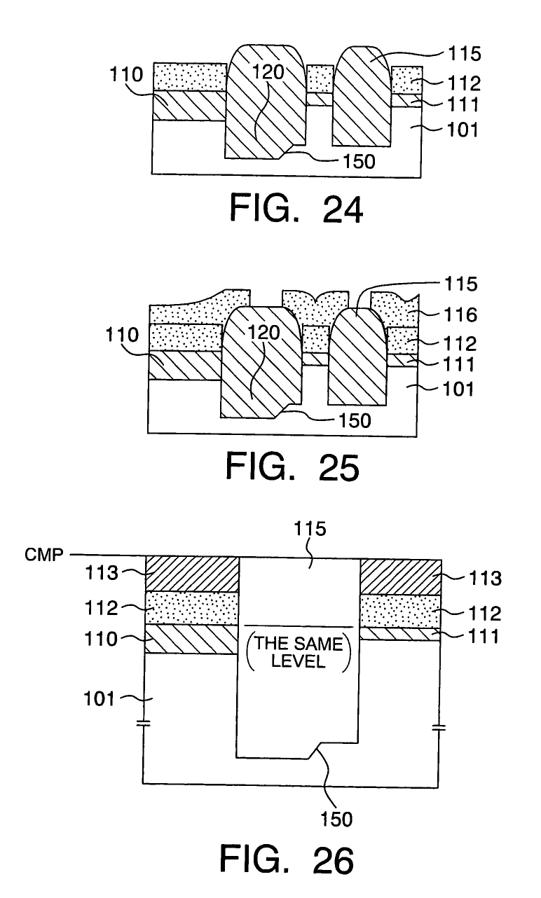

As shown in FIG. 24, the silicon oxide film 113 on the polysilicon film 112 is removed by RIE, chemical dry etching, or wet etching using phosphoric acid or the like.

Then, a process of removing a natural oxide film on the surface of the polysilicon film 112 is performed. After that, a polysilicon film is deposited, and a gate electrode 116 as a second layer is formed through photolithography and RIE as shown in FIG. 25.

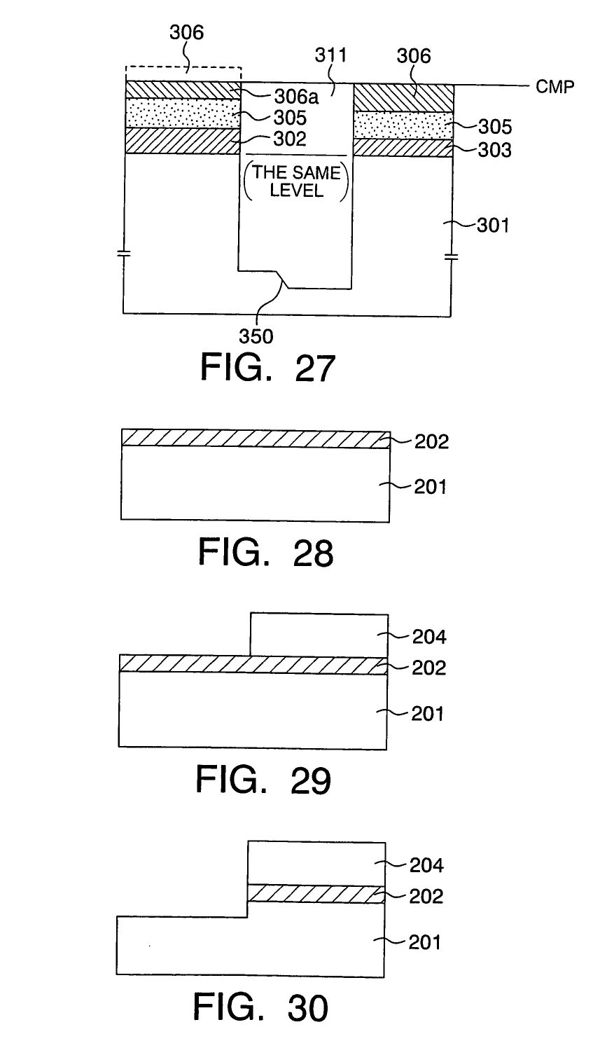

FIG. 26 is a longitudinal sectional view in one step of the semiconductor device according to this embodiment. FIG. 27 is a longitudinal sectional view in one step of a conventional semiconductor device.

In the conventional semiconductor device as shown in FIG. 27, a semiconductor substrate 301 has the same height in a region where a thick gate insulating film 302 is formed and in a region where a thick gate insulating film 303 is formed. The height of the semiconductor substrate 301 means the distance from the semiconductor substrate rear surface (the surface on which none of gate oxide films and the like are formed) to the surface on which the gate insulating films 302 and 303 are formed. Accordingly, the surface heights of the gate insulating films 302 and 303 have a difference corresponding to the film thickness difference, and this changes the surface height of the silicon nitride film 306 on the gate insulating films 302 and 303. As described above, a silicon oxide film 311 on the silicon nitride film 306 must be completely removed. When CMP is performed to a position shown in FIG. 27, a silicon nitride film 306a in the region where the thick gate insulating film 302 is formed becomes thinner than a silicon nitride film 306b in the region where the thin gate insulating film 303 is formed. Consequently, when the silicon oxide film 311 is etched, a large amount of the silicon oxide film 311 is removed on the side of the silicon nitride film 306a, thereby removing a portion close to the gate insulating film 302. This leads to an oxide film defect.

On the other hand, in this embodiment as shown in FIG. 26, the height of the semiconductor substrate 101 in the region in which the thick gate insulating film 110 is formed is different from that of the semiconductor substrate 101 in the region in which the thin gate insulating film 111 is formed, so as to absorb the difference between the heights of the gate insulating films 110 and 111. This makes the surface heights of the gate insulating films 110 and 11 substantially equal to each other, and makes the heights of the silicon nitride films 113 on the gate insulating films 110 and 111 substantially equal to each other. Accordingly, in the step of performing CMP for the silicon oxide film 115, the silicon nitride films 113 on the gate insulating films 110 and 111 having different film thicknesses can stop CMP at the same height.

In this embodiment as described above, the surface of the substrate 101 is lowered in the region in which the thick gate insulating film 110 is to be formed. Accordingly, on the surface on which the polysilicon film 112 as a gate electrode material is to be formed, the surfaces of the gate insulating films 110 and 111 differing in film thickness have almost no step and are flat. This makes it possible to avoid problems such as an initial defect of the gate insulating film, a short device life, and a leak to the semiconductor substrate, which occur if element isolation is performed by depositing a gate electrode material on the surfaces of gate insulating films having different film thicknesses with a step present between these gate insulating films.

### (2) Second Embodiment

FIGS. 28 to 41 illustrate the arrangement of a semiconductor device according to the second embodiment of the present invention and a method of fabricating the same.

In this embodiment, the arrangement of the first embodiment described above is partially changed. In the above first embodiment as shown in FIGS. 12 to 25, the silicon nitride film 103 is formed on the silicon oxide film 102, and the resist film 104 is used as a mask to remove by wet etching the silicon oxide film 102 and silicon nitride film 103 in the region where a thick gate insulating film is to be formed. In the second embodiment, no silicon nitride film is formed on a silicon oxide film, and a silicon oxide film in a region where a thick gate insulating film is to be formed is removed by RIE, not by wet etching.

As shown in FIG. 28, a silicon oxide film 202 about 1,000 Å thick is formed on a semiconductor substrate 201. As described above, no silicon nitride film for protecting a region except for a region where a thick gate insulating film is to be formed is formed on the silicon oxide film 202.

In this state, as shown in FIG. 29, a resist film 204 is formed on the silicon oxide film 202 by photolithography except for the region where a thick gate insulating film is to be formed.

As shown in FIG. 30, the resist film 204 is used as a mask to perform RIE for the silicon oxide film 202, thereby removing the silicon oxide film 202 from the region not covered with the mask to expose the surface of the semiconductor substrate 201. At the same time, a surface portion of the semiconductor substrate is etched away by an amount (in this embodiment, about 320 Å) corresponding to the difference between the film thicknesses of gate insulating films.

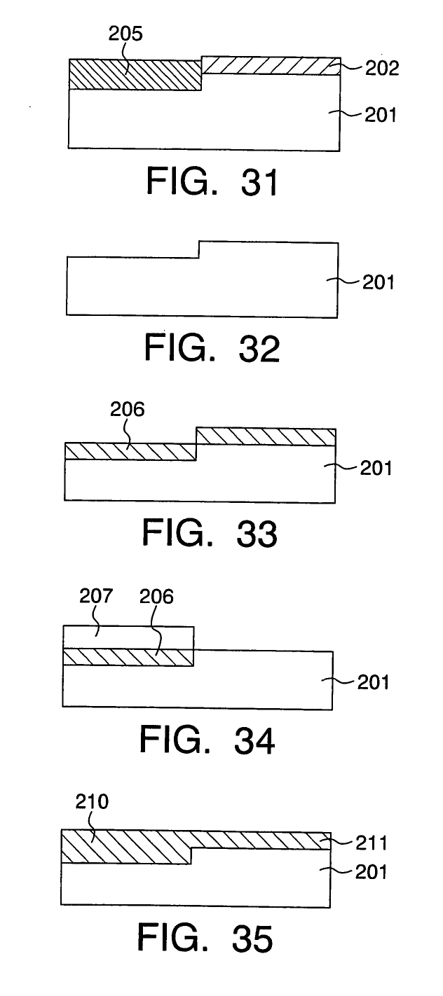

As shown in FIG. 31, a silicon oxide film 205 about 640 Å is formed in the region not covered with the silicon nitride film 202 by thermal oxidation. In this oxidation step, LOCOS or the like can also be used. The silicon oxide film 205 is formed to remove impurities from the substrate surface roughened by the RIE step.

Consequently, a step (in this embodiment, about 320 Å thick) is formed on the substrate level between the surface of the semiconductor substrate 201 in the region where the silicon oxide film 205 is formed, and the surface of the semiconductor substrate 201 in the region in which the silicon oxide film 202 is formed without forming the silicon oxide film 205.

This step on the substrate level is formed for the same reason as in the first embodiment; when gate insulating films having different film thicknesses are formed in subsequent steps, the surfaces of these gate insulating films are planarized.

As shown in FIG. 32, the silicon oxide films 202 and 205 are removed by wet etching using hydrogen fluoride, ammonium fluoride, or the like, thereby exposing the surface of the semiconductor substrate 201.

The subsequent steps are the same as in the first embodiment. As shown in FIG. 33, to form a thick gate insulating film, a silicon oxide film 206 having a thickness of, e.g., 320 Å is formed in the region where a thick gate insulating film is to be formed and in a region where a thin gate insulating film is to be formed.

As shown in FIG. 34, a resist film 207 which protects the region where a thick gate insulating film is to be formed is formed by photolithography. Wet etching is performed by using the resist film 207 as a mask to remove the silicon oxide film 206 from the region where a thin gate insulating film is to be formed.

As shown in FIG. 35, a silicon oxide film about 80 Å thick is formed on the entire surface, a gate insulating film 210 about 400 Å thick is formed in the region where a thick gate insulating film is to be formed, and a gate insulating film 211 about 80 Å thick is formed in the region where a thin gate insulating film is to be formed.

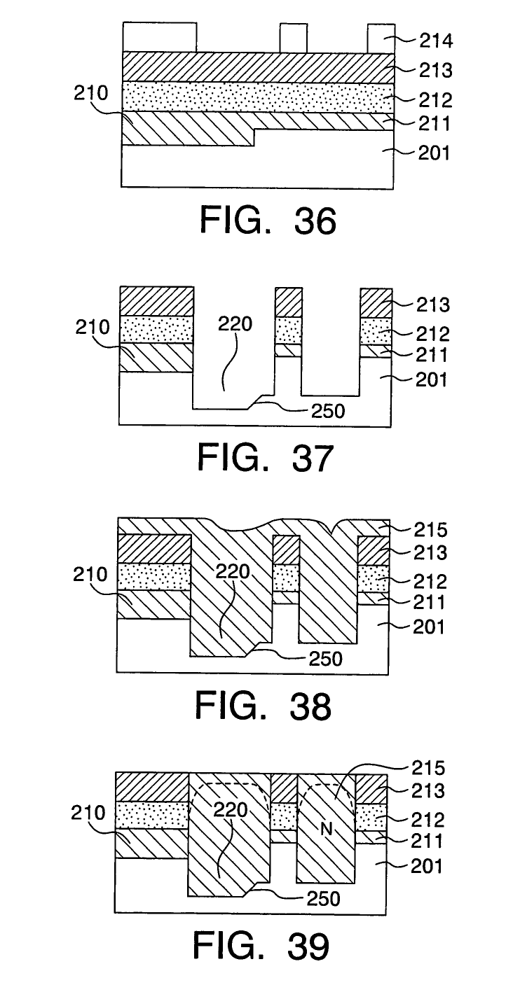

As shown in FIG. 36, on the gate insulating films 210 and 211, a polysilicon film 212 about 100 Å thick and a silicon nitride film 213 about 1,000 Å thick serving as a polishing stopper in CMP are formed in this order. In addition, a resist film 214 for protecting an active region is formed by photolithography except for an element isolation region.

As shown in FIG. 37, the resist film 214 is used to pattern the polysilicon film 212 and silicon nitride film 213, and a trench 220 is formed in the semiconductor substrate 201 in the element isolation region by RIE.

As in the first embodiment, a step 250 which rises from the region where the thick gate insulating film 210 is formed toward the region where the thin gate insulating film 211 is formed is formed on the bottom surface of the trench 220 in the semiconductor substrate 201.

As shown in FIG. 38, a silicon oxide film 215 is deposited to fill the trench 220 by CVD. As shown in FIG. 39, the silicon nitride film 213 is used as a stopper to perform CMP, thereby planarizing the silicon oxide film 215.

To reduce the step beside the element isolation region, wet etching is performed for the silicon oxide film 215 in the element isolation region by using ammonium fluoride or the like, thereby decreasing the height as indicated by a dotted line N.

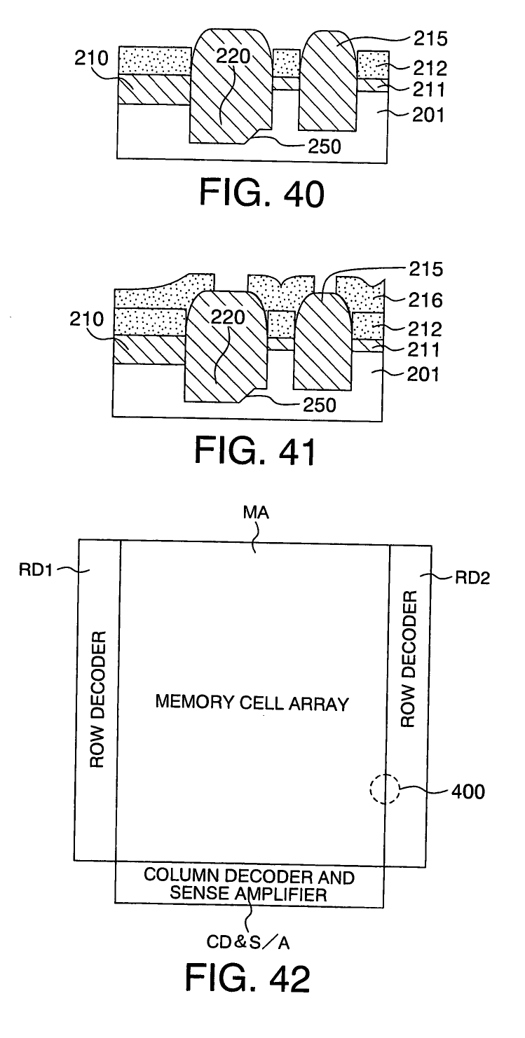

As shown in FIG. 40, the silicon oxide film 213 on the polysilicon film 212 is removed by RIE, chemical dry etching, or wet etching using phosphoric acid or the like. After a natural oxide film on the surface of the polysilicon film 212 is removed, a polysilicon film is deposited, and a gate electrode 216 is formed through photolithography and RIE as shown in FIG. 41.

In this embodiment, as in the first embodiment described previously, on the surface on which the polysilicon film 212 as a gate electrode material is to be formed, the surfaces of the gate insulating films 210 and 211 differing in film thickness have almost no step and are flat. This makes it possible to avoid problems such as an initial defect of the gate insulating film, a short device life, and a leak to the semiconductor substrate.

In each of the above embodiments, the film thickness of the thick oxide film is 400 Å, the film thickness of the thin oxide film is 80 Å, and the step is 320 Å, but the present invention is not limited to these thicknesses. However, the step is desirably about the difference between the thick and thin gate oxide films, and need only be about half the difference.

The first and second embodiments described above are merely examples and hence do not limit the present invention. For example, gate oxide films may be formed not only by thermal oxidation but also by CVD, a film such as a Ta₂O₅ film having a higher dielectric constant than that of a silicon oxide film may also be formed, and thick and thin oxide films may be partially different in material. Likewise, the gate electrode material is not limited to polysilicon but may be a refractory metal or a stacked electrode of polysilicon and a refractory metal.

The formation method, film thickness, and material of each film can be changed as needed.

### (3) Third Embodiment

A nonvolatile semiconductor memory according to the third embodiment of the present invention will be described below with reference to FIGS. 42 to 44. In this embodiment, the structure of the first or second embodiment described above is applied to a nonvolatile semiconductor memory.

FIG. 42 shows an outline of the arrangement of a nonvolatile semiconductor memory, particularly a NAND flash memory, according to this embodiment.

This semiconductor memory comprises a memory cell array MA, row decoders RD1 and RD2 separately arranged on the left and right sides of the memory cell array MA, and a column decoder and sense amplifier CD & S/A.

The memory cell array MA has a plurality of NAND cell blocks. In each block, a plurality of memory cell transistors are connected in series so that adjacent transistors share a source or drain, and selection transistors are arranged on the two sides of these memory cell transistors.

In the memory cell array MA, the row decoder RD1 or RD2 selects a word line, and memory cell transistors connected to this word line are selected.

The column decoder and sense amplifier CD & S/A selects a bit line, and memory cell transistors connected to this bit line are selected and subjected to write or read.

In each cell transistor of the memory cell array MA, a floating gate electrode is formed via a thin gate insulating film (tunnel insulating film) formed on a semiconductor substrate. In addition, a control gate electrode is stacked on this floating gate electrode via an interpoly dielectric film (e.g., an ONO film). A low voltage VCC is supplied to these transistors.

The row decoders RD1 and RD2 and column decoder and sense amplifier CD & S/A are peripheral circuits and required to have a high breakdown voltage because a program voltage VPP higher than the low voltage VCC is supplied. Therefore, the row decoders RD1 and RD2 and column decoder and sense amplifier CD & S/A are made up of transistors having a gate insulating film thicker than the gate insulating film (tunnel insulating film) of the cell transistors in the memory cell array MA.

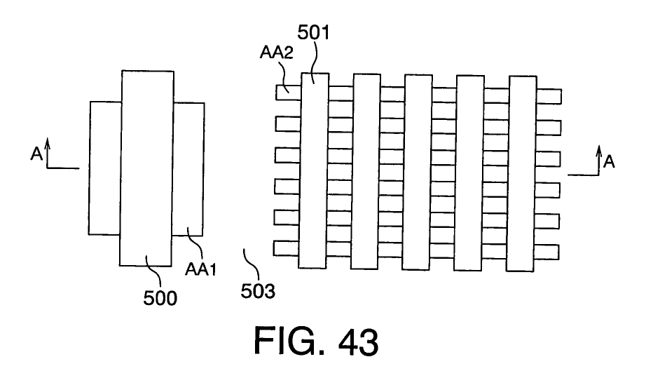

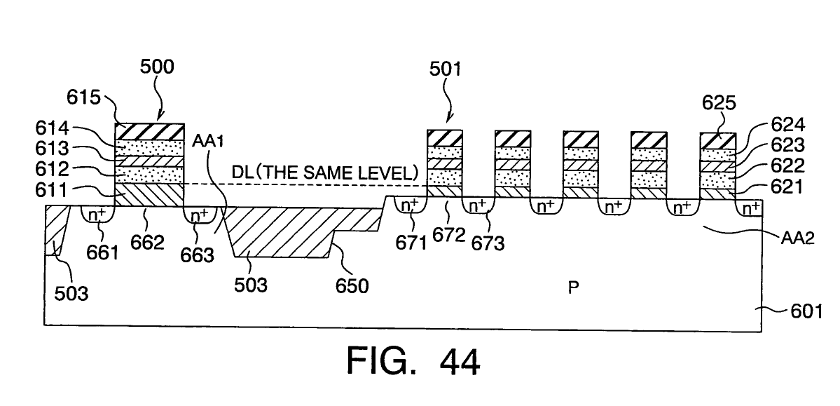

A portion 400 in FIG. 42 is shown in an enlarged scale in FIG. 43. FIG. 43 is a plan view showing an outline of the arrangement of transistors in the peripheral circuits and transistors in the memory cell array MA. FIG. 44 is a longitudinal sectional view taken along a line A-A in FIG. 43.

A transistor in the peripheral circuits has a source region 661, channel region 662, and drain region 663 formed in an active region AA1 defined by an element isolation region (STI) on the surface of a semiconductor substrate 601, and a gate electrode 500 formed on the channel region 662 via a thick gate insulating film 611.

A transistor in the memory cell array MA has a source region 671, channel region 672, and drain region 673 formed in an active region AA2 defined by the element isolation region (STI) on the surface of the semiconductor substrate 601, and a gate electrode 501 formed on the channel region 672 via a thin gate insulating film 621. As described above, these transistors are connected in series so that adjacent transistors share a source or drain region.

A silicon oxide film 503 is formed in the element isolation region (shallow trench isolation, to be referred to as STI hereinafter) between the active regions AA1 and AA2.

As shown in FIG. 44, in a surface portion of the semiconductor substrate 601, the thick gate insulating film 611 is formed on the peripheral circuit side and the thin gate insulating film (tunnel insulating film) 621 is formed on the memory cell array MA side through steps similar to those in the first or second embodiment.

The surface heights of the gate insulating films 611 and 621 are substantially the same.

In the peripheral circuit, the active regions AA1 of the individual transistors are isolated by the STI. Likewise, the active region AA2 in which the cell array is formed in the memory cell array MA and the active region AA1 in the peripheral circuit are also isolated.

In the STI between the peripheral circuit and the memory cell array MA, a step 650 is present on the bottom surface of the semiconductor substrate 601 as in the first and second embodiments. The step 650 rises from the peripheral circuit in which the thick gate insulating film 611 is formed toward the memory cell array MA in which the thin gate insulating film 621 is formed.

In the memory cell array MA, a polysilicon film 622 serving as a floating gate electrode, an interpoly dielectric film 623 made of an ONO film or the like, a polysilicon film 624 serving as a control gate electrode, and a control gate resistance decreasing metal film 625 made of tungsten (W) or tungsten silicide (WSi) are stacked in this order on the surface of the gate insulating film 621, thereby forming the gate electrode 501.

In the peripheral circuit, the floating gate electrode of the memory cell transistor is unnecessary. Since, however, the peripheral circuit transistors are fabricated by the same process as the memory cell transistors, a gate electrode made of the same material and having the same thickness as the floating gate electrode is formed.

That is, a polysilicon film 612 serving as a floating gate electrode, an interpoly dielectric film 613, a polysilicon film 614 serving as a control gate electrode, and a control gate resistance decreasing metal film 615 are stacked in this order on the surface of the gate insulating film 611, thereby forming the gate electrode 500.

The silicon oxide film 503 is formed between the STIs.

In this embodiment, an arrangement similar to that of the first or second embodiment is applied to a nonvolatile semiconductor memory. Therefore, in the peripheral circuit in which the thick gate insulating film 611 is formed, the surface of the semiconductor substrate 601 is made lower than that in the memory cell array MA in which the thin gate insulating film 621 is formed. As a consequence, the surfaces of the polysilicon films 612 and 622 as floating gate electrode materials have almost no step and are flat.

This makes it possible to avoid conventional problems such as an initial defect of the gate insulating film, a short device life, and a leak to the semiconductor substrate.

As the fourth embodiment of the present invention, an electric card using the nonvolatile semiconductor memory according to the third embodiment of the present invention, and as the fifth embodiment of the present invention, an electric device using this electric card will be described below.

### (4) Fourth and Fifth Embodiments

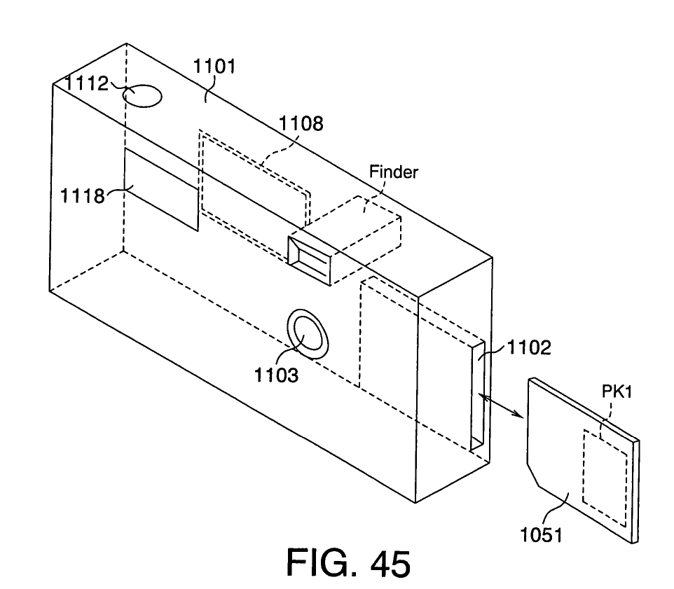

FIG. 45 shows an electric card according to the fourth embodiment and the arrangement of an electric device using this electric card according to the fifth embodiment.

This electric device is a digital still camera as an example of portable electric devices. The electric card is a memory card 1051 used as a recording medium of a digital still camera 1101. This memory card 1051 incorporates an IC package PK1 in which the nonvolatile semiconductor memory according to the third embodiment described above is integrated or encapsulated.

The case of the digital still camera 1101 accommodates a card slot 1102 and a circuit board (not shown) connected to this card slot 1102.

The memory card 1051 is detachably inserted in the card slot 1102 of the digital still camera 1101. When inserted in this card slot 1102, the memory card 1051 is electrically connected to electronic circuits on the circuit board.

If this electric card is a non-contact-type IC card, the electric card is electrically connected to the electronic circuits on the circuit board by radio signals when inserted in or approached to the card slot 1102.

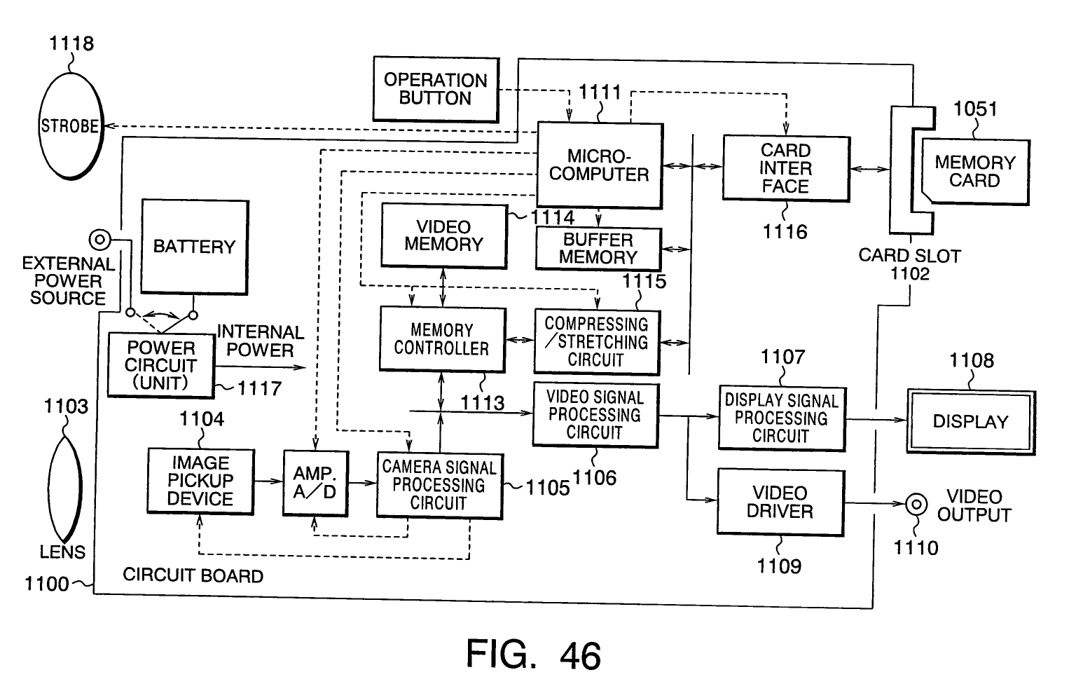

FIG. 46 shows the basic arrangement of the digital still camera.

Light from an object is converged by a lens 1103 and input to an image pickup device 1104. This image pickup device 1104 is, e.g., a CMOS sensor and photoelectrically converts the input light to output, e.g., an analog signal. This analog signal is amplified by an analog amplifier (AMP) and converted into a digital signal by an A/D converter. The converted signal is input to a camera signal processing circuit 1105 where the signal is subjected to automatic exposure control (AE), automatic white balance control (AWB), color separation, and the like, and converted into a luminance signal and color difference signals.

To monitor the image, the output signal from the camera signal processing circuit 1105 is input to a video signal processing circuit 1106 and converted into a video signal. The system of this video signal is e.g., NTSC (National Television System Committee).

The video signal is output to a display 1108 attached to the digital still camera 1101, via a display signal processing circuit 1107. This display 1108 is, e.g., a liquid crystal monitor.

The video signal is supplied to a video output terminal 1110 via a video driver 1109. An image picked up by this digital still camera 1101 can be output to an image apparatus such as a television set via the video output terminal 1110. This allows the pickup image to be displayed on an image apparatus other than the display 1108. A microcomputer 1111 controls the image pickup device 1104, analog amplifier (AMP), A/D converter (A/D), and camera signal processing circuit 1105.

To capture an image, an operator presses an operation button such as a shutter button 1112. Accordingly, the microcomputer 1111 controls a memory controller 1113 to write the output signal from the camera signal processing circuit 1105 into a video memory 1114 as a frame image. This frame image written in the video memory 1114 is compressed on the basis of a predetermined compression format by a compressing/stretching circuit 1115. The compressed image is recorded, via a card interface 1116, on the memory card 1051 inserted in the card slot.

To reproduce a recorded image, an image recorded on the memory card 1051 is read out via the card interface 1116, stretched by the compressing/stretching circuit 1115, and written in the video memory 1114. The written image is input to the video signal processing circuit 1106 and displayed on the display 1108 or another image apparatus in the same manner as when an image is monitored.

In this arrangement, components mounted on the circuit board 1100 are the card slot 1102, image pickup device 1104, analog amplifier (AMP), A/D converter (A/D), camera signal processing circuit 1105, video signal processing circuit 1106, display signal processing circuit 1107, video driver 1109, microcomputer 1111, memory controller 1113, video memory 1114, compressing/stretching circuit 1115, and card interface 1116.

The card slot 1102 need not be mounted on the circuit board 1100, and can also be connected to the circuit board 1100 by a connector cable or the like.

A power circuit 1117 is also mounted on the circuit board 1100. This power circuit 1117 receives power from an external power source or battery and generates an internal power source voltage used inside the digital still camera 1101. For example, a DC-DC converter can be used as this power circuit 1117. The internal power source voltage is supplied to the individual circuits described above and to a strobe 1118 and the display 1108.

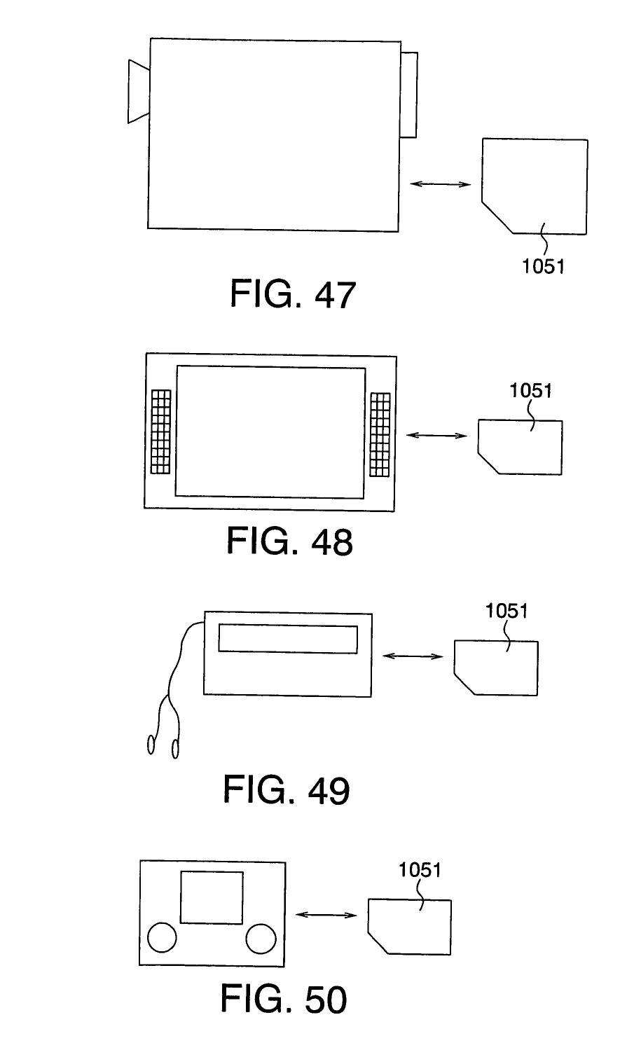

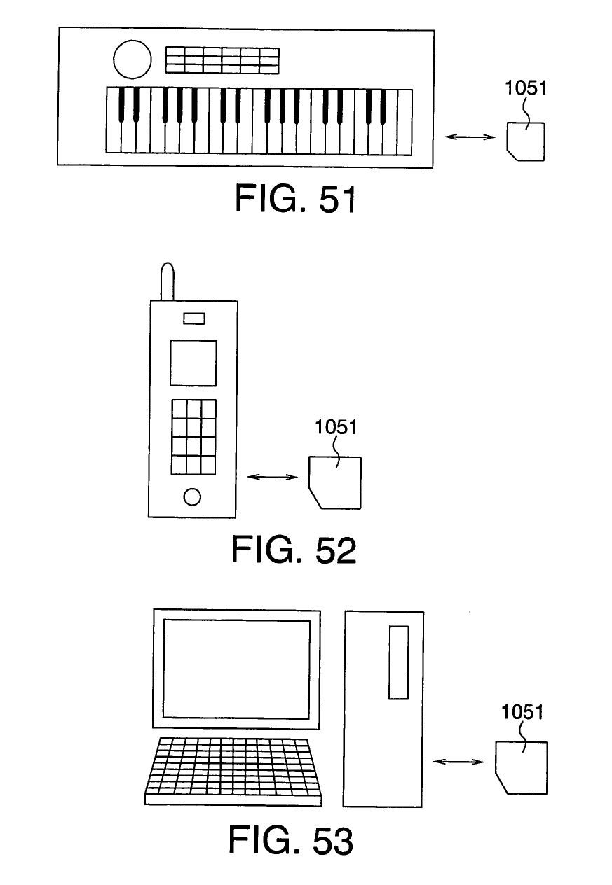

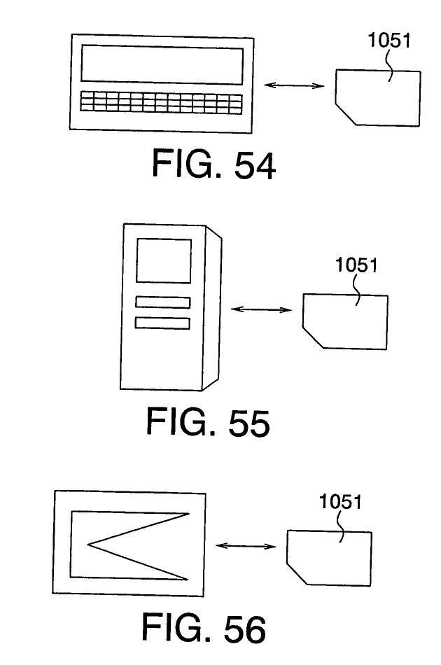

As described above, the electric card according to this embodiment can be used in portable electric devices such as the digital still camera explained above. However, this electric card can also be used in various apparatuses such as shown in FIGS. 47 to 56, as well as in portable electric devices. That is, the electric card can also be used in a video camera shown in FIG. 47, a television set shown in FIG. 48, an audio apparatus shown in FIG. 49, a game apparatus shown in FIG. 50, an electric musical instrument shown in FIG. 51, a cellular phone shown in FIG. 52, a personal computer shown in FIG. 53, a personal digital assistant (PDA) shown in FIG. 54, a voice recorder shown in FIG. 55, and a PC card shown in FIG. 56.

In the embodiments as described above, although gate insulating films having different film thicknesses are formed, the surface of a semiconductor substrate in a first active region in which a thick gate insulating film is to be formed is made lower than that of the semiconductor substrate in a second active region in which a thin gate insulating film is to be formed. Since this reduces a step between the gate insulating film surfaces, a defect of the gate insulating film and the like can be prevented in the step of forming gate electrodes on these gate insulating films or in the step of forming an element isolation region between the first and second active regions. As a consequence, the yield can be improved.

The above embodiments are merely examples and hence do not limit the present invention. Accordingly, these embodiments can be variously modified without departing from the technical scope of the present invention.

What is claimed is:

1. A semiconductor device comprising:
a first gate insulating film formed in a first active region of a semiconductor substrate and having a first film thickness; and
a second gate insulating film formed in a second active region of said semiconductor substrate and having a second film thickness smaller than the first film thickness,
wherein a surface of the semiconductor substrate in the first active region is lower than that in the second active region.

2. The device according to claim 1,
wherein the semiconductor substrate surface in the first active region is lower than that in the second active region by an amount corresponding to a difference between the first and second film thicknesses, so a surface height of said first gate insulting film is substantially equal to that of said second gate insulating film.

3. The device according to claim 1,
wherein the first and second active regions are isolated by a trench filled with an insulating film, and
a gate electrode is formed on each of said first and second gate insulating films.

4. The device according to claim 3,
wherein said gate electrodes on said first and second gate insulating films are made of the same material and have substantially the same thickness.

5. A semiconductor device comprising:
a first gate insulating film formed in a first active region of a semiconductor substrate and having a first film thickness;
a second gate insulating film formed in a second active region of said semiconductor substrate and having a second film thickness smaller than the first film thickness; and
a trench element isolation insulating region formed between the first and second active regions,
wherein a first height which is a surface height of said semiconductor substrate in the first active region on a bottom surface of the trench element isolation region is lower than a second height which is a surface height of said semiconductor substrate in the second active region on the bottom surface of the trench element isolation region.

6. The device according to claim 5,
wherein a difference between the first and second film thicknesses is ½ to twice a difference between the first and second heights.

7. A method of fabricating a semiconductor device comprising a first gate insulating film formed in a first active region of a semiconductor substrate and having a first film thickness, and a second gate insulating film formed in a second active region of the semiconductor substrate and having a second film thickness smaller than the first film thickness, comprising:
processing a surface portion of the semiconductor substrate such that a semiconductor substrate surface in the first active region is lower than that in the second active region.

8. The method according to claim 7,
wherein when the surface portion of the semiconductor substrate is processed, the semiconductor substrate surface in the first active region is made lower than that in the second active region by an amount corresponding to a difference between the first and second film thicknesses, to make a surface height of the first gate insulting film substantially equal to that of the second gate insulating film.

9. A semiconductor device fabrication method comprising:
forming a mask which exposes a surface of a first active region and covers a second active region of a semiconductor substrate;
forming a first oxide film on the surface of the first active region by oxidation by using the mask;
removing the mask and first oxide film to make a semiconductor substrate surface in the first active region lower than that in the second active region;
forming a second oxide film on the surfaces of the first and second active regions;
leaving a portion of the second oxide film which exists in the first active region and removing a portion of the second oxide film which exists in the second active region; and
forming a third oxide film thinner than the second oxide film on a surface of the second oxide film in the first active region of the semiconductor substrate, and forming a fourth oxide film having a film thickness substantially equal to that of the third oxide film on the surface of the second active region,
wherein a first gate insulating film including the second and third oxide films is formed in the first active region, a second gate insulating film including the fourth oxide film in the second active region, and a surface height of the first gate insulating film is substantially equal to that of the second gate insulating film.

10. The method according to claim 9, further comprising:
depositing a first film made of a conductive material on the third and fourth oxide films, and depositing a second film serving as a polishing stopper on the first film;
patterning the first and second films into an electrode shape in the first and second active regions, and forming a trench in a surface portion of the semiconductor substrate in an element isolation region between the first and second active regions;
depositing an insulating film on an entire surface;
planarizing the insulating film by using the second film as a polishing stopper;
etching the insulating film in the element isolation region to decrease a height of the insulating film;
removing the second film;
depositing a third film made of a conductive material on an entire surface; and
patterning the third film into an electrode shape in the first and second active regions.

11. A nonvolatile semiconductor memory comprising a memory cell array and peripheral circuit,
wherein a transistor included in said peripheral circuit has a first gate insulating film formed in a first active region of a semiconductor substrate and having a first film thickness,
a transistor included in said memory cell array has a second gate insulating film formed in a second active region of said semiconductor substrate and having a second film thickness smaller than the first film thickness, and
a semiconductor substrate surface in the first active region is lower than that in the second active region.

12. The memory according to claim 11,
wherein the semiconductor substrate surface in the first active region is lower than that in the second active region by an amount corresponding to a difference between the first and second film thicknesses, so a surface height of said first gate insulating film is substantially equal to that of said second gate insulating film.

13. The memory according to claim 11,
wherein the first and second active regions are isolated by a trench filled with an insulating film, and
on each of said first and second gate insulating films, a floating gate electrode, interpoly dielectric film, control gate electrode, and control gate resistance decreasing metal film are formed.

14. The memory according to claim 11,
wherein in said memory cell array, a plurality of memory cell transistors are connected in series such that adjacent transistors share a source and drain, and selection transistors are arranged on two sides of said plurality of memory cell transistors.

15. A nonvolatile semiconductor memory comprising a memory cell array and peripheral circuit,
wherein a transistor included in said peripheral circuit has a first gate insulating film formed in a first active region of a semiconductor substrate and having a first film thickness,
a transistor included in said memory cell array has a second gate insulating film formed in a second active region of said semiconductor substrate and having a second film thickness smaller than the first film thickness, and
on a bottom surface of a trench element isolation insulating region formed between the first and second active regions, a first height of a surface of said semiconductor substrate in the first active region is lower than a second height of the surface of said semiconductor substrate in the second active region.

16. The memory according to claim 15,
wherein in said memory cell array, a plurality of memory cell transistors are connected in series such that adjacent transistors share a source and drain, and selection transistors are arranged on two sides of said plurality of memory cell transistors.

17. A method of fabricating a nonvolatile semiconductor memory comprising a memory cell array and peripheral circuit,
wherein a transistor included in the peripheral circuit has a first gate insulating film having a first film thickness in a first active region of a semiconductor substrate, and,
a transistor included in the memory cell array has a second gate insulating film having a second film thickness smaller than the first film thickness in a second active region of the semiconductor substrate, and
the method comprises, processing a surface portion of the semiconductor substrate such that a surface of the semiconductor substrate in the first active region is lower than that of the semiconductor substrate in the second active region.

18. The method according to claim 17,
wherein the surface of the semiconductor substrate in the first active region is lower than that of the semiconductor substrate in the second active region by an amount corresponding to a difference between the first and second film thicknesses, so a surface height of the first gate insulating film is substantially equal to that of the second gate insulating film.

19. The semiconductor device,
wherein an electronic card comprises the nonvolatile semiconductor memory set forth in claim 11.

20. An electronic apparatus comprising:
a card interface;
a card slot connected to said card interface; and
an electronic card capable of being electrically connected to said card slot,
wherein said electronic card comprises the nonvolatile semiconductor memory set forth in claim 11.

21. The semiconductor device,
wherein an electronic card comprises the nonvolatile semiconductor memory set forth in claim 15.

22. An electronic apparatus comprising:
a card interface;
a card slot connected to said card interface; and
an electronic card capable of being electrically connected to said card slot,
wherein said electronic card comprises the nonvolatile semiconductor memory set forth in claim 15.

23. The apparatus according to claim 20,
wherein said electronic apparatus is a digital still camera.

24. The apparatus according to claim 20,
wherein said electronic apparatus is a video camera.

25. The apparatus according to claim 20,
wherein said electronic apparatus is a television.

26. The apparatus according to claim 20,
wherein said electronic apparatus is an audio apparatus.

27. The apparatus according to claim 20,
wherein said electronic apparatus is a game apparatus.

28. The apparatus according to claim 20,
wherein said electronic apparatus is an electronic musical instrument.

29. The apparatus according to claim 20,
wherein said electronic apparatus is a cellular phone.

30. The apparatus according to claim 20,
wherein said electronic apparatus is a personal computer.

31. The apparatus according to claim 20,
wherein said electronic apparatus is a personal digital assistant.

32. The apparatus according to claim 20,
wherein said electronic apparatus is a voice recorder.

33. The apparatus according to claim 20,
wherein said electronic apparatus is a PC card.
